(19) United States
(12) Patent Application Publication
(10) Pub. No.: US 2003/0209808 A1
(43) Pub. Date: Nov. 13, 2003

(54) Semiconductor device having semiconductor chips mounted on package substrate

(75) Inventor: Shinji Baba, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/283,208

(22) Filed: Oct. 30, 2002

(30) Foreign Application Priority Data
May 7, 2002 (JP) 2002-131505

(51) Int. Cl. H01L 23/48

(52) U.S. Cl. 257/777

(57) ABSTRACT

A first semiconductor chip is disposed in an opening of a package substrate, and a second semiconductor chip is disposed so as to face the first semiconductor chip and interconnected through a bump. The second semiconductor chip is electrically connected to a plurality of input terminals of the package substrate through the bump. The package substrate comprises a multi-layer wiring connected to the plurality of input terminals and formed in the substrate, and comprises a plurality of output terminals connected to the multi-layer wiring. Solder balls connected to the output terminals are provided on the back of the package substrate.

### BACKGROUND OF THE INVENTION

1. Field of the Invention

The present invention relates to a semiconductor device, and more specifically to a multi-chip module comprising a plurality of semiconductor chips mounted on a package substrate.

2. Description of the Background Art

FIG. 10 is a perspective view for illustrating a conventional semiconductor device; and FIG. 11 is a sectional view for illustrating the conventional semiconductor device. In FIGS. 10 and 11, reference numeral 10 denotes a plurality of semiconductor chips, 20 denotes a package substrate as a high-density wiring substrate for mounting the plurality of semiconductor chips 10, 3 denotes bumps consisting of a material such as solder, 4 denotes solder balls, 5 denotes an under-fill resin, and 8 denotes a system substrate for mounting the package substrate 20.

In a conventional semiconductor device, as FIGS. 10 and 11 show, the plurality of semiconductor chips 10 are two-dimensionally mounted on the package substrate 20 through the bumps 3 for applications requiring the provision of a large number of input/output terminals, or for applications requiring an electrically and thermally high performance. Such a semiconductor device is generally referred to as a multi-chip module.

However, conventional semiconductor devices, particularly multi-chip modules have the following problems. Namely, although the number of input/output terminals from and to the system substrate 8 is reduced by sending and receiving signals within the module, if further improvement of the performance of the two-dimensional multi-chip module system is required, the outer dimensions of the system are increased.

If the outer dimensions of the system are increased, since the warp of the substrate will occur due to difference in the coefficients of thermal expansion between the semiconductor chip 10 and the package substrate 20, the alignment accuracy of terminals will lower, and mounting on the system substrate 8 will become difficult; therefore, the reliability of packaging will be lowered.

Especially, since the outer dimensions are limited to about 50 mm square in a BGA (ball grid array) type, PGA (pin grid array) type may be adopted in a region with large outer dimensions and a large number of terminals. In this case, however, since sockets must be provided between the semiconductor chips and the system substrate, the manufacturing costs increase.

When a large number of input/output terminals are required, the connection distance of semiconductor chips 10 increases in the two-dimensional multi-chip module, and high-speed transmission performance between semiconductor chips cannot be fully exerted.

In the case of multi-chip modules, the shape or the number of terminals differs depending the systems, and the common use of the sockets or the system substrate is difficult, leading to increase in the costs.

Furthermore, rework for removing a semiconductor device or multi-chip module once mounted on a system substrate for replacement due to breakdown or improvement of the performance of the system, and for mounting the semiconductor device or multi-chip module again on the system substrate, is difficult in the BGA type

As described above, the conventional semiconductor devices that are required to have higher performance lead to a larger system size, and cause the following problems:

(1) the lower yield due to the difficulty in mounting;

(2) the necessity of provision of sockets to ensure the mounting reability; and

(3) the difficulty in reworking.

This also causes a much higher cost for their production.

Although a technique to mount semiconductor chips three-dimensionally has been proposed for reducing the mounting area, it cannot be applied to the case where a high electrical performance is required, for example, a large number of input/output terminals are required.

In order to maintain stable system operation, heat dissipation of semiconductor chips must be raised.

### SUMMARY OF THE INVENTION

The present invention has been conceived to solve the previously-mentioned problems and a general object of the present invention is to provide a novel and useful semiconductor device.

A more specific object of the present invention is to provide a highly integrated semiconductor device having a large number of input/output terminals.

The above object of the present invention is attained by a following semiconductor device.

According to one aspect of the present invention, the semiconductor device comprises a substrate having an opening. The substrate has a plurality of input terminals formed on the surface of the substrate, a multi-layer wiring formed in the substrate and connected to the input terminals, and a plurality of output terminals connected to the multi-layer wiring. A first semiconductor chip is disposed in the opening. A second semiconductor chip is disposed so as to face the first semiconductor chip and is electrically connected to the first semiconductor chip and the input terminals.

According to another aspect of the present invention, the semiconductor device comprises a substrate having an opening. The substrate has a plurality of input terminals formed on the surface of the substrate, a multi-layer wiring formed in the substrate and connected to the input terminals, and a plurality of output terminals connected to the multi-layer wiring. A semiconductor chip disposed above the opening and electrically connected to the input terminals. A chip capacitor disposed on the semiconductor chip so as to face the opening.

Other objects and further features of the present invention will be apparent from the following detailed description when read in conjunction with the accompanying drawings.

### BRIEF DESCRIPTION OF THE DRAWINGS

FIG. 1A is a sectional view for illustrating the structure of a semiconductor device according to First Embodiment;

FIG. 1B is a sectional view for illustrating a package substrate in a semiconductor device according to First Embodiment (No. 1);

FIG. 1C is a sectional view for illustrating a package substrate in a semiconductor device according to First Embodiment (No. 2);

FIG. 2 is a sectional view for illustrating a semiconductor device according to Second Embodiment of the present invention;

FIG. 3 is a sectional view for illustrating a semiconductor device according to Third Embodiment of the present invention;

FIG. 4 is a sectional view for illustrating a semiconductor device according to Fourth Embodiment of the present invention;

FIG. 5 is a sectional view for illustrating a semiconductor device according to Fifth Embodiment of the present invention;

FIG. 6 is a sectional view for illustrating a semiconductor device according to Sixth Embodiment of the present invention;

FIG. 7 is a sectional view for illustrating a semiconductor device according to Seventh Embodiment of the present invention;

FIG. 8 is a sectional view for illustrating a semiconductor device according to Eighth Embodiment of the present invention;

FIG. 9 is a sectional view for illustrating a semiconductor device according to Ninth Embodiment of the present invention;

FIG. 10 is a perspective view for illustrating a conventional semiconductor device; and

FIG. 11 is a sectional view for illustrating the conventional semiconductor device.

### DETAILED DESCRIPTION OF THE PREFERRED EMBODIMENTS

In the following, principles and embodiments of the present invention will be described with reference to the accompanying drawings. The members and steps that are common to some of the drawings are given the same reference numerals and redundant descriptions therefore may be omitted.

First Embodiment

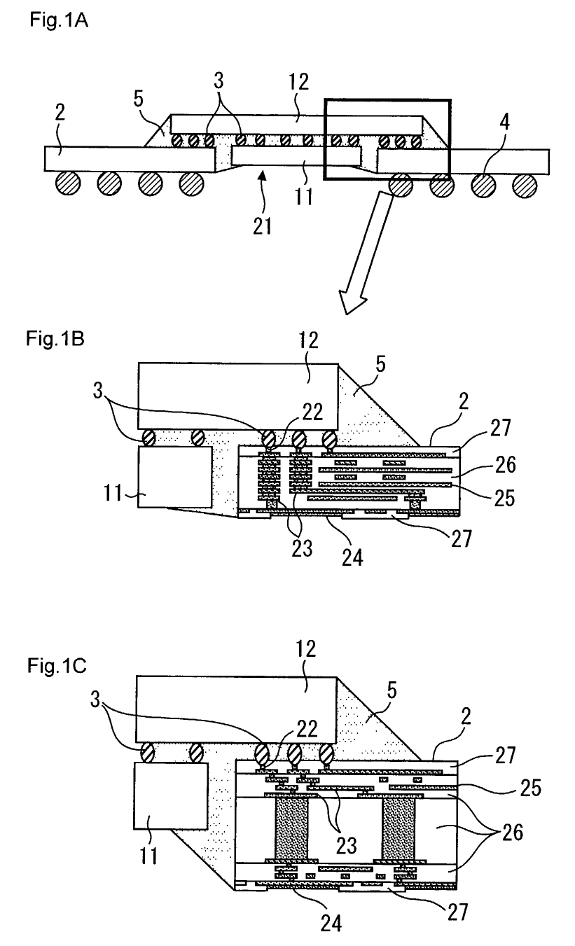

FIGS. 1A to 1C are sectional views for illustrating a semiconductor device according to First Embodiment of the present invention. Specifically, FIG. 1A is a sectional view for illustrating the structure of a semiconductor device according to First Embodiment; FIG. 1B is a sectional view for illustrating a package substrate in a semiconductor device according to First Embodiment (No. 1); and FIG. 1C is a sectional view for illustrating a package substrate in a semiconductor device according to First Embodiment (No. 2).

In FIGS. 1A to 1C, reference numeral 11 denotes a first semiconductor chip; 12 denotes a second semiconductor chip; 2 denotes a package substrate; 21 denotes an opening; 22 denotes input terminals; 23 denotes multi-layer wirings; 24 denotes output terminals; 25 denotes a power source/ground plane; 26 denotes interlayer resins; 27 denotes insulating films; 3 denotes bumps consisting of a material such as solder; 4 denotes solder balls as conductive members; and 5 denotes an under-fill resin.

As FIG. 1A shows, an opening 21 of a predetermined size is formed in the package substrate 2, and a first semiconductor chip 11 is disposed in the opening 21. A second semiconductor chip 12 larger than the first semiconductor chip 11 is disposed above the package substrate 2 so as to face the first semiconductor chip 11. Here, the two semiconductor chips 11 and 12 are disposed so that the surfaces thereof face to each other, and electrically connected through bumps 3. As FIG. 1B shows, the second semiconductor chip 12 is electrically connected to a plurality of input terminals 22 on the package substrate 2 through the bumps 3. Solder balls 4 connected to a plurality of output terminals 24 (refer to FIG. 1B) are formed on the back of the package substrate 2. Also, although not shown, the package substrate 2 is mounted on a system substrate through the solder balls 4.

As FIG. 1B shows, the package substrate 2 comprises a plurality of input terminals 22 formed on the surface thereof, multi-layer wirings 23 formed inside thereof and connected to the input terminals 22, and a plurality of output terminals 24 formed on the back thereof and connected to the multi-layer wirings 23.

The package substrate 2 also comprises a power source plane or a ground plane 25 (hereafter referred to as “power source/ground plane”).

In the package substrate 2, the multi-layer wirings 23 are insulated from the power source/ground plane 25 by the interlayer resin 26.

The package substrate 2 also comprises insulating films 27 on the surface and the back thereof in order to ensure that adjacent input terminals 22 and output terminals 24 are insulated from each other. For the insulation of the input terminals 22 and the output terminals 24, a resin may be used in place of the insulating films 27.

The package substrate 2 has substantially the same coefficient of thermal expansion as the coefficient of thermal expansion of the system substrate whereon the package substrate 2 is mounted.

The package substrate 2 shown in FIG. 1B is only an example, and this may be a package substrate having a large via hole inside as FIG. 1C shows. Furthermore, the number of input/output terminals may be adequately changed depending on the required performance of the system.

To summarize the semiconductor device according to First Embodiment, the first semiconductor chip 11 is disposed in the opening 21 formed on the package substrate 2, and the second semiconductor chip 12 is disposed so as to face the first semiconductor chip 11. The first semiconductor chip 11 is electrically connected to the second semiconductor chip 12 through the bumps 3. The second semiconductor chip 12 is also electrically connected to the plurality of input terminals 22 on the package substrate 2 through the bumps 3. The package substrate 2 comprises the multi-layer wirings 23 connected to input terminals 22 and formed in the substrate 2, and the plurality of output terminals 24 connected to the multi-layer wirings 23. The package substrate 2 also comprises the solder balls 4 connected to the output terminals 24 and formed on the back of the package substrate 2.

According to First Embodiment, since the package substrate 2 has the multi-layer wirings 23 and a large number of input/output terminals 22, 24, a large number of inputs and outputs can be performed through a number of arrays of bumps 3 and solder balls 4.

Also according to First Embodiment, a first semiconductor chip 11 is disposed in the opening 21 of the package substrate 2, and a second semiconductor chip 12 is three-dimensionally disposed above the first semiconductor chip 11 and the package substrate 2. Thereby, increase in the density and the reduction of the size of a semiconductor device can be realized, and packaging properties on a system substrate can be improved.

Furthermore, since a plurality of semiconductor chips are mounted through a package substrate 2 having substantially the same coefficient of thermal expansion as the coefficient of thermal expansion of the system substrate, and the size of the semiconductor device of First Embodiment can be more reduced than that of the conventional semiconductor device, and a high reliability can be achieved.

Therefore, the manufacturing costs of the semiconductor device can be reduced. Also, since a plurality of semiconductor chips can be connected in the shorter distance than conventional two-dimensional multi-chip modules, the transmitting properties between chips can be raised to a limit. By using the semiconductor device according to First Embodiment, the effect of high density and high performance increases with increase in the number of input/output terminals.

In First Embodiment, a power source/ground plane 25 is provided in the package substrate 20. Thereby, the effect of power source/ground noise reduction can be improved, and high-speed transmission can be possible.

Second Embodiment

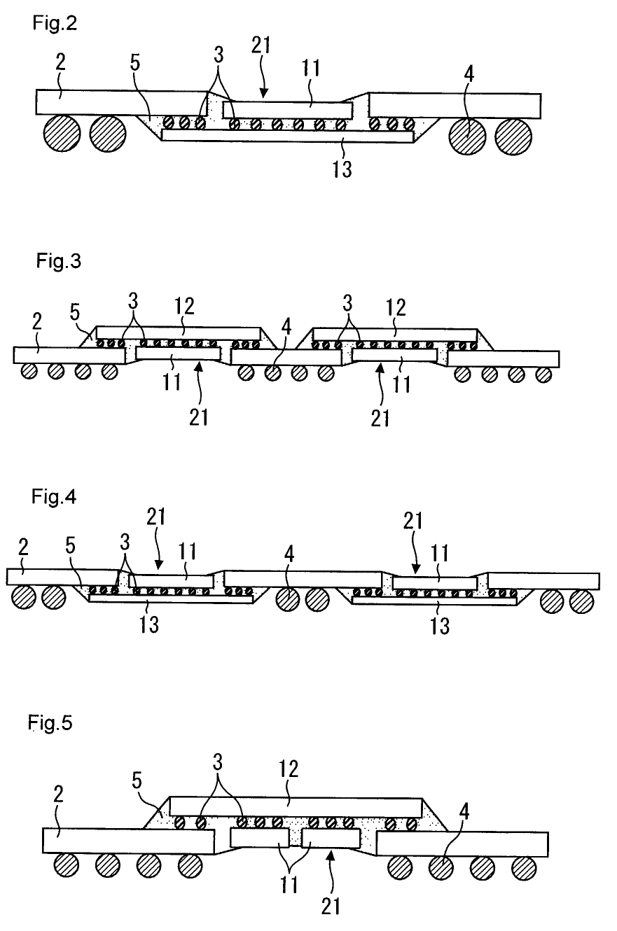

FIG. 2 is a sectional view for illustrating a semiconductor device according to Second Embodiment of the present invention.

As FIG. 2 shows, in Second Embodiment, a second semiconductor chip 13 is thinner than the diameter (thickness) of a solder ball 4, and the second semiconductor chip 13 is disposed on the side of the solder balls 4. The first semiconductor chip 11 is disposed in the opening 21 of the package substrate 2, so that the surface of the circuit faces down, that is, so as to face the surface of the circuit of the second semiconductor chip 13 facing up. Since other constitutions are substantially the same as First Embodiment, the description thereof will be omitted.

According to Second Embodiment, in addition to the effect of First Embodiment, further reduction of the thickness of the semiconductor device can be realized. Namely, the density of the semiconductor device can further be raised, and the size thereof can further be reduced. Thereby, the semiconductor device can be mounted on the location having the limitation of the height. Second Embodiment is suitable for the system having small mounting intervals.

Third Embodiment

FIG. 3 is a sectional view for illustrating a semiconductor device according to Third Embodiment of the present invention.

As FIG. 3 shows, according to Third Embodiment, a plurality of openings 21 are formed in a package substrate 2, each of a plurality of first semiconductor chips 11 are disposed in each of the openings 21, and a plurality of second semiconductor chips 12 are disposed so that the surfaces of the circuits thereof face the surfaces of the first semiconductor chips 11. The first semiconductor chips 11 are electrically connected to the second semiconductor chips 12 through bumps 3. Namely, a plurality of semiconductor chips 11 and second semiconductor chips 12 according to First Embodiment are mounted on the package substrate 2. Since other constitutions are substantially the same as First Embodiment, the description thereof will be omitted.

According to Third Embodiment, in addition to the effect obtained by First Embodiment, a semiconductor device that can correspond to further improvement of performance can be provided.

Fourth Embodiment

FIG. 4 is a sectional view for illustrating a semiconductor device according to Fourth Embodiment of the present invention.

As FIG. 4 shows, in Fourth Embodiment, a plurality of first semiconductor chips 11 and second semiconductor chips 13 according to Second Embodiment are mounted on a package substrate 2. Specifically, a plurality of openings 21 are formed in the package substrate 2, and a semiconductor chip 11 is disposed in each of the openings 21. Furthermore the second semiconductor chips 13 are disposed in the side of solder balls 4 so that the surfaces of the circuits of the chips 13 face the surfaces of the first semiconductor chips 11. Here, the second semiconductor chips 13 are made thinner than the thickness of a solder ball 4.

According to Fourth Embodiment, the same effect as in Second Embodiment and Third Embodiment can be obtained.

Fifth Embodiment

FIG. 5 is a sectional view for illustrating a semiconductor device according to Fifth Embodiment of the present invention.

As FIG. 5 shows, in Fifth Embodiment, a plurality of first semiconductor chips 11 are disposed in the opening 21 of the package substrate 2, and one second semiconductor chip 12 is disposed so as to face the first semiconductor chips 11. These are electrically connected to each other. Namely, in First Embodiment, a plurality of first semiconductor chips 11 are disposed in the opening 21 formed in the package substrate 2.

According to Fifth Embodiment, even when complex functions are required to the system, a semiconductor device with integrated functions can easily be realized. This is because the package substrate 2 is a substrate having fine multi-layer wirings 23 (refer to FIGS. 1B and 1C); therefore, the freedom of design is large.

In addition, although two first semiconductor chips 11 and a second semiconductor chip 12 are interconnected, three or more first semiconductor chips 11 may be connected. Thus, even when a number of first semiconductor chips 11 are used, the package substrate 2 can accommodate these semiconductor chips because the package substrate 2 has a number of input terminals 22, output terminals 24, and multi-layer wirings 23.

Sixth Embodiment

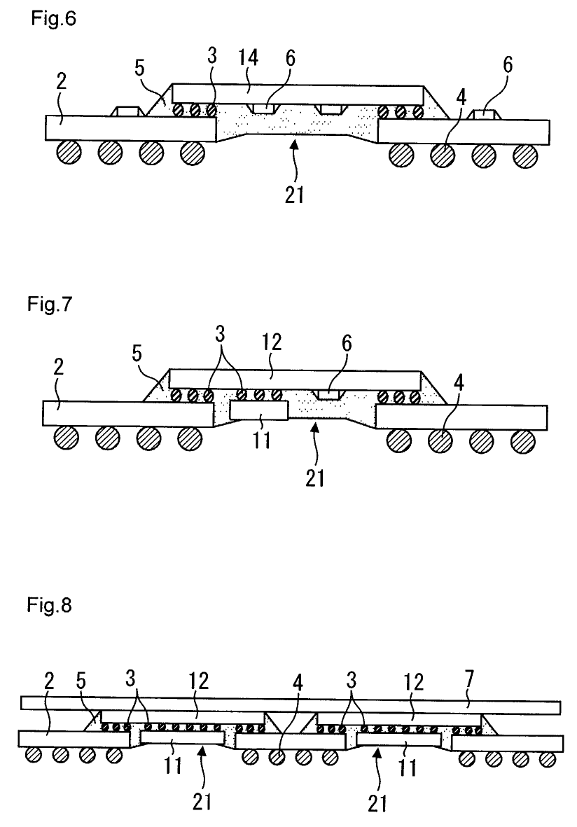

FIG. 6 is a sectional view for illustrating a semiconductor device according to Sixth Embodiment of the present invention.

In Sixth Embodiment, a plurality of chip capacitors 6 are mounted on the bump 3 side of the second semiconductor chip 12 in place of the first semiconductor chips 11 in Fifth Embodiment.

According to Sixth Embodiment, chip capacitors 6 can be mounted directly on a semiconductor chip 14, unlike a conventional multi-chip module comprising chip capacitors 6 on the package substrate 2. Therefore, electrical properties are significantly improved, a high-speed performance can be achieved, and power source noise can be reduced. Also, the power source/ground voltage level can be stabilized.

Although chip capacitors 6 are mounted on the package substrate 2 in Sixth Embodiment, mounting on the substrate 2 may be determined depending on the required performance.

Seventh Embodiment

FIG. 7 is a sectional view for illustrating a semiconductor device according to Seventh Embodiment of the present invention.

As FIG. 7 shows, in Seventh Embodiment, a chip capacitor 6 is further mounted on the bump 3 side of the second semiconductor chip 12 in a semiconductor device according to First Embodiment. Namely, both a first semiconductor chip 11 and the chip capacitor 6 are mounted on the second semiconductor chip 12.

Seventh embodiment enables freedom of the design of a high-performance system, particularly high-speed transmission and the strengthened power source.

Eighth Embodiment

FIG. 8 is a sectional view for illustrating a semiconductor device according to Eighth Embodiment of the present invention.

As FIG. 8 shows, in Eighth Embodiment, a heat dissipation plate 7 is provided on the backs of a plurality of second semiconductor chips 12 in the semiconductor device of Third Embodiment.

According to Eighth Embodiment, since heat accumulated in the semiconductor ships 12 is directly dissipated from the chips 12 to the heat dissipation plate 7, a high heat-dissipation effect can be obtained. Although heat accumulated in the semiconductor ships 12 is also dissipated from the first semiconductor ships 11 connected through bumps 3, since the distances between the two semiconductor chips 11 and 12 are short, a high heat-dissipation effect can be obtained.

In Eighth Embodiment, although a heat dissipation plate 7 is provided on the backs of second semiconductor chips 12 in the semiconductor device of Third Embodiment, the present invention is not limited thereto, but the heat dissipation plate 7 can be provided on the semiconductor chips of First Embodiment, Third Embodiment, and fifth to Seventh Embodiments.

In place of an integrated heat dissipation plate 7 as in Eighth Embodiment, an individual heat dissipation plate may be provided on each semiconductor chip.

Ninth Embodiment

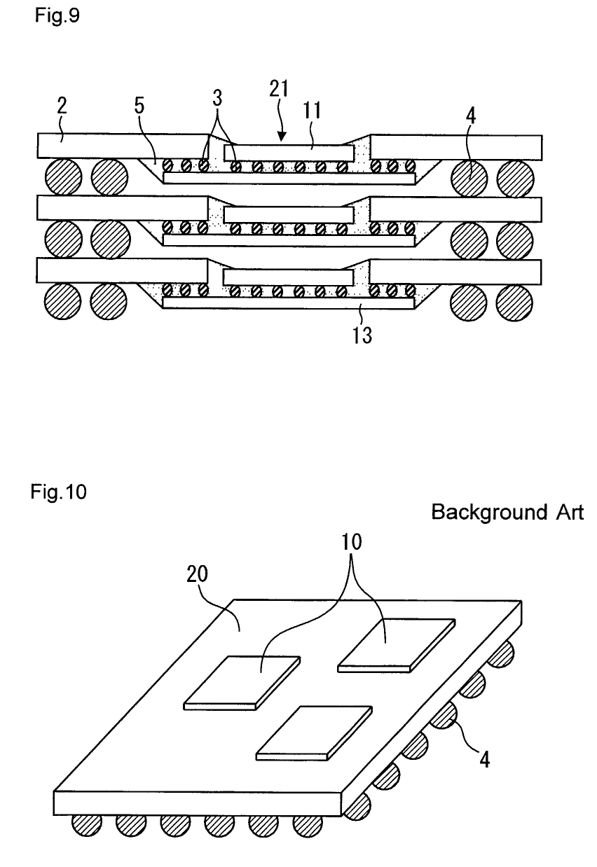

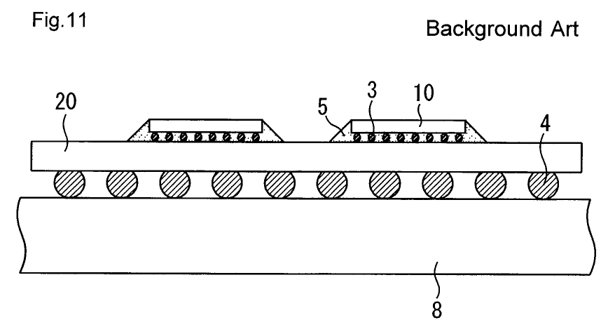

FIG. 9 is a sectional view for illustrating a semiconductor device according to Ninth Embodiment of the present invention.

As FIG. 9 shows, in Ninth Embodiment, a plurality of the semiconductor devices according to Second Embodiment are three-dimensionally packaged.

According to Ninth Embodiment, high-density packaging can easily be performed even in further complex systems, and a high-speed performance can be realized in a small area.

In Ninth Embodiment, although a plurality of semiconductor devices according to Second Embodiment are three-dimensionally laminated, this can be applied to semiconductor devices according to Fourth Embodiment. In this case, the density of semiconductor devices can be still higher.

This invention, when practiced illustratively in the manner described above, provides the following major effects:

According to the present invention, a highly integrated semiconductor device having a large number of input/output terminals can be provided.

Further, the present invention is not limited to these embodiments, but variations and modifications may be made without departing from the scope of the present invention.

The entire disclosure of Japanese Patent Application No. 2002-131505 filed on May 7, 2002 containing specification, claims, drawings and summary are incorporated herein by reference in its entirety.

What is claimed is:

1. A semiconductor device comprising:
a substrate having an opening, said substrate having: a plurality of input terminals formed on the surface of said substrate; a multi-layer wiring formed in said substrate and connected to said input terminals; and a plurality of output terminals connected to said multi-layer wiring;
a first semiconductor chip disposed in the opening; and
a second semiconductor chip disposed so as to face said first semiconductor chip and electrically connected to said first semiconductor chip and said input terminals.

2. The semiconductor device according to claim 1, further comprising:
a chip capacitor facing the opening on said second semiconductor chip.

3. The semiconductor device according to claim 1, wherein a plurality of said first semiconductor chips is disposed in the opening.

4. The semiconductor device according to claim 1, further comprising:
a heat dissipating member on said second semiconductor chip.

5. The semiconductor device according to claim 1, further comprising:
a plurality of conductive members each connected to said plurality of output terminals, and
wherein the thickness of said second semiconductor chip is made thinner than the thickness of said conductive members, and said second semiconductor chip is disposed on the side of said conductive members.

6. The semiconductor device according to claim 5, wherein a laminate of a plurality of said substrates is provided.

7. A semiconductor device comprising:
a substrate having an opening, said substrate having: a plurality of input terminals formed on the surface of said substrate;
a multi-layer wiring formed in said substrate and connected to said input terminals; and a plurality of output terminals connected to said multi-layer wiring;
a semiconductor chip disposed above the opening and electrically connected to said input terminals; and
a chip capacitor disposed on said semiconductor chip so as to face the opening.

8. The semiconductor device according to claim 7, further comprising:
a chip capacitor on said substrate.

9. The semiconductor device according to claims 7, further comprising:
a heat dissipating member on said semiconductor chip.

10. The semiconductor device according to claim 1, further comprising:
a power source plane or a ground plane in said substrate.

11. The semiconductor device according to claim 7, further comprising:
a power source plane or a ground plane in said substrate.

12. The semiconductor device according to claim 1, wherein said substrate has a plurality of the openings.

13. The semiconductor device according to claim 7, wherein said substrate has a plurality of the openings.
